(19) United States
(12) Patent Application Publication
(10) Pub. No.: US 2021/0083148 A1
(43) Pub. Date: Mar. 18, 2021

(54) HIGH POWER LED CHIP BACK ELECTRODE INTEGRATED PACKAGE MODULE WITH STAND

(71) Applicant: SHENZHEN BIUE SPECTRUM RICK TECHNOLOGY CO., LTD, Guangdong (CN)

(72) Inventor: Hesheng ZHANG, Guangdong (CN)

(21) Appl. No.: 16/959,698

(22) PCT Filed: Aug. 20, 2018
(86) PCT No.: PCT/CN2018/101282

§ 371 Date: Jul. 2, 2020

(30) Foreign Application Priority Data
Jul. 13, 2018 (CN) 201810768905.1
Jul. 13, 2018 (CN) 201821109407.8
Jul. 13, 2018 (CN) 201821109422.2
Jul. 13, 2018 (CN) 201821110133.4

(51) Int. Cl. H01L 33/38; H01L 33/58

(52) U.S. Cl. CPC H01L 33/382; H01L 33/483; H01L 33/387; H01L 33/58

(57) ABSTRACT

The present invention provides a high power LED chip back electrode integrated package module with a stand, comprising a substrate, a lens stand, and a tens made of glasses. The lens stand is provided above the substrate and wraps same, and is provided with a fixed cavity where the lens is placed; the lens is provided in the fixed cavity and is connected to the lens stand; the substrate comprises a first line layer, a first ceramic layer, and a first metal layer which are connected sequentially; a first electrode connection disk is provided at both ends of the first metal layer; the first electrode connection disk is connected to the first line layer, and is in pressure connection to an external component; the first line layer is provided with multiple first LED chip units; the lens is provided above the first LED chip units and corresponds to the position thereof. The present invention further provide another high power LED chip back electrode integrated package module with a stand. According to the present invention, the electrode connection disk is isolated from the outside to prevent external impurities from contaminating the electrode connection disk.

### BACKGROUND OF THE INVENTION

The invention relates to a high-power LED chip back electrode integrating and packaging module provided with a holder.

The electrode terminal blocks of existing high-power LED chip packaging modules are disposed on a circuit layer, namely the emergent sides of LED chips, and are connected to external components by welding, which has the detects that the electrode terminal blocks exposed to the outside may be contaminated by external impurities and even short circuits between the electrode terminal blocks may be caused, thus resulting in damage to the LED chips and potential safety hazards.

Hence, improvements should be made to overcome the above-mentioned defects.

### BRIEF SUMMARY OF THE INVENTION

One objective of the invention is to overcome the defects of the prior art by providing a high-power LED chip back electrode integrating aid packaging module provided with a holder.

The technical solution of the invention is as follows:

A high-power LED chip back electrode integrating and packaging module provided with a holder comprises a substrate, a lens holder, and a lens made of glass, wherein the lens holder is disposed over the substrate, wraps the substrate, and has a fixing cavity for accommodating the lens, and the lens is disposed in the fixing cavity and is connected to the lens holder;

The substrate comprises a first circuit Layer, a first ceramic layer and a first metal layer, wherein the first circuit layer is disposed over the first ceramic layer and is connected to the first ceramic layer the first metal layer is disposed under the first ceramic layer and is connected to the first ceramic layer, and first electrode terminal blocks are disposed at two ends of the first metal layer, are connected to the first circuit layer, and are connected to external components by crimping; and

A plurality of first LED chip units are disposed on the first circuit layer, and the lens is disposed over the first LED chip units and corresponds to the first LED chip units in position.

Furthermore, the substrate is a DPC substrate or a DBC substrate.

Furthermore, the lens is a one-stage lens, which is a planar lens, a cylindrical lens, a lens group, or an integral array lens.

Furthermore, the lens is a two-stage lens which comprises a primary lens and a secondary lens, wherein the secondary lens is disposed over the primary lens and corresponds to the primary lens in position, the primary lens is a lens group, an integral array lens or a cylindrical lens, and the secondary lens is a planar lens.

Furthermore, the first ceramic layer is made of aluminum nitride or aluminum oxide.

Furthermore the lens holder is made of metal or ceramic.

Another objective of the invention is to provide a high-power LED chip back electrode integrating and packaging module provided with a holder, which comprises a substrate, a lens holder, and a lens made of glass, wherein the lens holder is disposed over the substrate, is connected to the substrate by sintering, and has a fixing cavity for accommodating the lens, and the lens is disposed in the fixing cavity and is connected to the lens holder;

The substrate comprises a die bonding layer, a second ceramic layer and a second metal layer, wherein the die bonding layer is disposed over the second ceramic layer and is connected to the second ceramic layer the second metal layer is disposed under the second ceramic layer and is connected to the second ceramic layer, a second circuit layer is disposed on the die bonding layer or the second ceramic layer, and second electrode terminal blocks are disposed at two ends of the second metal layer, are connected to the die bonding layer, and are connected to external components by crimping;

A plurality of second LED chip units are disposed on the die bonding layer, and the lens is disposed over the second LED chip units and correspond to the second LED chip units in position.

Furthermore, the substrate is a multi-layer sintered ceramic substrate.

Furthermore, the lens is a one-stage lens, which is a planar lens, a cylindrical lens, a lens group, or an integral array lens.

Furthermore the lens is a two-stage lens which comprises a primary lens and a secondary lens, wherein the secondary lens is disposed over the primary lens and corresponds to the primary lens in position, the primary lens is a lens group, an integral array lens or a cylindrical lens, and the secondary lens is a planar lens.

By adoption of the aforesaid technical solutions, the invention has the following beneficial effects;

(1) The module of the invention is simple and firm in structure, easy to assemble and convenient to replace, thus saving time;

(2) The ceramic layer improves the heat dissipation effect and the operating stability and is resistant to high temperature and aging, thus having a longer service life;

(3) The electrode terminal blocks are isolated from the outside and are prevented from being contaminated by external impurities, so that the electrode terminal blocks are better protected, the service life of products is prolonged, the products can be used more safely, the stability of the products is improved, and the high voltage isolation requirements of electronic products are satisfied;

(4) The electrode terminal blocks are connected to external components by crimping, so that the process is made simpler and faster; and

(5) The lens made of glass guarantees the light output efficiency, better protects the LED chips, is not prone to aging, simplifies the structure of products, is convenient to clean, and saves costs.

### BRIEF DESCRIPTION OF THE DRAWINGS

To more clearly explain the technical solutions of the embodiments of the invention, the accompanying drawings required for the description of the embodiments or the prior art are briefly introduced below. Obviously, the drawings in the following description are only for some embodiments of the invention and those ordinarily skilled in the art can obtain other drawings according to the following ones without creative labor.

FIG. 1 is a first structural diagram of a substrate of the invention;

FIG. 2 is a second structural diagram of the substrate of the invention;

FIG. 3 is a first structural diagram of an embodiment of the invention;

FIG. 4 is a second structural diagram of the embodiment of the invention;

FIG. 5 is a third structural diagram of the embodiment of the invention;

FIG. 6 is a fourth structural diagram of the embodiment of the invention;

FIG. 7 is a fifth structural diagram of the embodiment of the invention;

### REFERENCE SIGNS IN THE FIGURES

1, substrate; 111, first circuit layer; 112, first ceramic layer; 113, first metal layer; 1131, first electrode terminal block; 121, die bonding layer; 122, second ceramic layer; 123, second metal layer, 1231, second electrode terminal block 131, first mounting hole; 132, third mounting hole; 133, fifth mounting hole; 2 lens holder; 21 second mounting hole; 22, fourth mounting hole; 23, sixth mounting hole; 24, ninth mounting hole; 3, fixing cavity; 31, notch; 32, inclined part; 4, planar lens; 5, cylindrical lens; 6, integral array lens; 7, lens group; 51, part; 52, flat part; 61, lens pressing piece; 62, lens connecting base; 63, array lens unit; 64, third screw; 611 seventh mounting hole; 612, eighth mounting hole.

### DETAILED DESCRIPTION OF THE INVENTION

For the sake of a better understanding of the technical issues to be settled by the invention as well as the technical solutions and beneficial effects of the invention, the invention is further expounded below in conjunction with the accompanying drawings and embodiments. Understandably, the specific embodiments described hereinafter are only used to explain the invention, and are not intended to limit the invention.

It should be noted that when one element is erred to as being “connected to” another element, this element is directly or indirectly connected to the other element. Moreover, the terms “first” and “second” are used only for the purpose of description, and do not indicate or imply relative importance or implicitly specify the quantity of the technical features referred to. Therefore, a feature defined by “first” and “second” may clearly or implicitly indicate that one or more of the feature: are included.

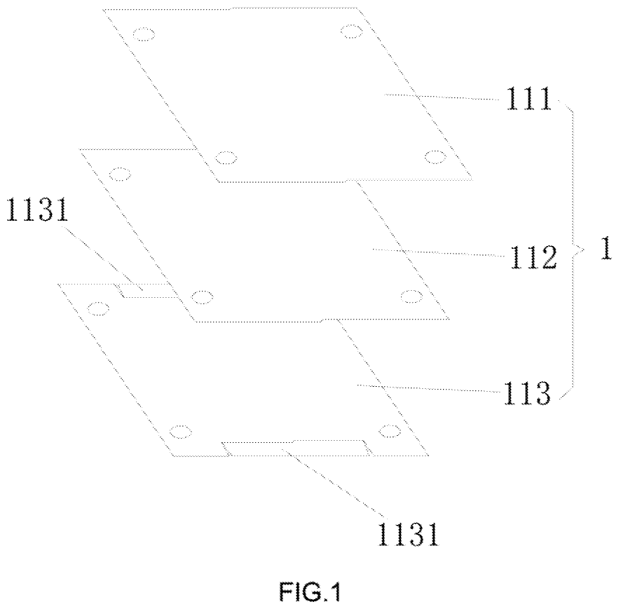

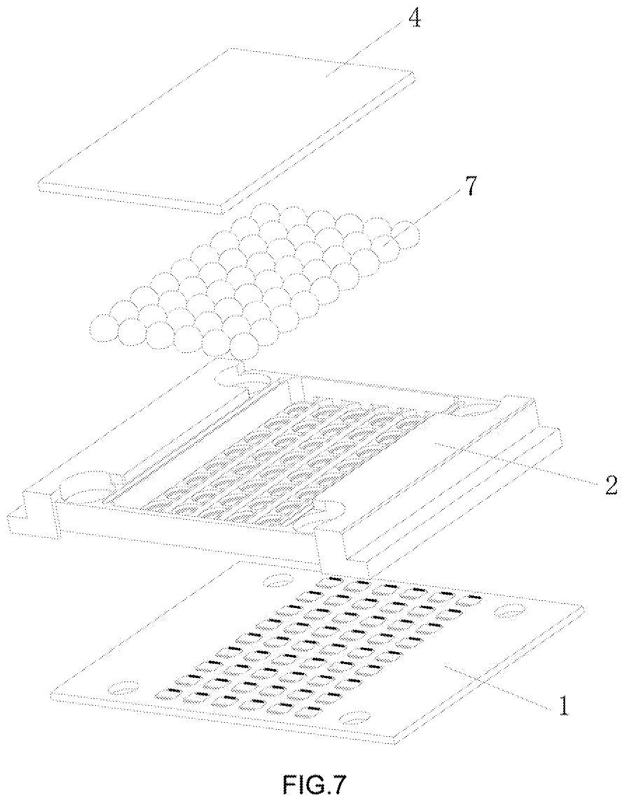

Referring to FIG. 1, FIG, and FIG. 7, a high-power LED chip back electrode integrating and packaging module provided with a holder comprises a substrate 1, a lens holder 2, and a lens made of glass, wherein the lens holder 2 is disposed over the substrate 1, wraps the substrate 1, and has a fixing cavity 3 for accommodating the lens, and the lens is disposed in the fixing cavity 3 and is connected to the lens holder 2;

The substrate 1 comprises a first circuit layer 111, a first ceramic layer 11 and a first metal layer 113, wherein the first circuit layer 111 is disposed over the first ceramic layer 112 and is connected to the first ceramic layer 112, the first metal layer 113 is disposed under the first ceramic layer 112 and is connected to the first ceramic layer 112, and first electrode terminal blocks 1131 are disposed at two ends of the first metal layer 113, are connected to the first circuit layer 111, and are connected to external components by crimping;

A plurality of first LED chip units (not shown, the same below) are disposed on the first circuit layer 111, and the lens is disposed over the first LED chip units and corresponds to the first LED chip units in position.

Preferably, the substrate 1 is a DPC substrate.

Preferably, the substrate 1 is a DBC substrate.

Preferably, the first electrode terminal blocks 1131 penetrate through the first ceramic layer 112 by means of conductive metal to be connected to the first circuit layer 111.

Preferably, the thickness of the first metal layer 113 is equal to that of the first circuit layer 111 to primarily prevent the substrate from buckling, so that the flatness of the substrate 1 is guaranteed.

Preferably, the plurality of first LED chip units are regularly disposed on the first circuit layer 111.

Preferably the plurality of first LED chip units are irregularly disposed on the first circuit layer 111.

Preferably, the first circuit layer 111 and the first metal layer 113 are both made of copper, which is a conducting medium and has good electrical conductivity and high cost performance.

Preferably, the first ceramic layer 112 is made of aluminum nitride, which can guarantee good heat conductivity and is non-conducting thus meeting the voltage isolation requirement. The first ceramic layer 112 made of aluminum nitride can be applied to high-power LED chips.

Preferably, the first ceramic layer 112 is made of aluminum oxide, which can guarantee good heat conductivity and is non-conducting, thus meeting the voltage isolation requirement. The first ceramic layer 112 made of aluminum alloy can be applied to low-power LED chips.

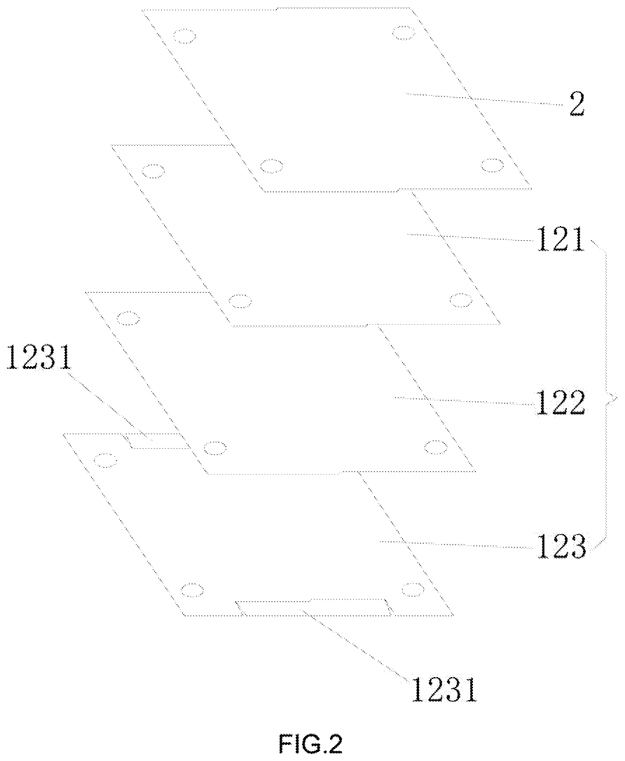

Referring to FIG. 2 to FIG. 7, another objective of the invention is to provide a high-power LED chip back electrode integrating and packaging module provided with a holder, which comprises a substrate 1, a lens holder 2, and a lens made of glass, wherein the lens holder 2 is disposed over the substrate 1, is connected to the substrate 1 by sintering, and has a fixing cavity 3 for accommodating the lens, and the lens is disposed in the fixing cavity 3 and is connected to the lens holder 2;

The substrate 1 comprises a die bonding layer 121 a second ceramic layer 122 and a second metal layer 123, wherein the die bonding layer 121 is disposed over the second ceramic layer 122 and is connected to the second ceramic layer 122, the second metal layer 123 is disposed under the second ceramic layer 122 and is connected to the second ceramic layer 122 a second circuit layer (not shown, the same below) is disposed on the die bonding layer 121 or the second ceramic layer 122, and second electrode terminal blocks 1231 are disposed at two ends of the second metal layer 123, are connected to the die bonding layer 121, and are connected to external components by crimping;

A plurality of second LED chip units (not shown, the same below) are disposed on the die bonding layer 121, and the lens is disposed over the second LED chip units and corresponds to the second LED chip units in position.

Preferably, the outline dimension of the substrate 1 is equal to that of the lens holder 2.

Preferably, the substrate 1 is a multi-layer sintered ceramic substrate.

Preferably, the second electrode terminal blocks 1231 penetrate through the second ceramic layer 122 by means of conductive metal to be connected to the die bonding layer 121.

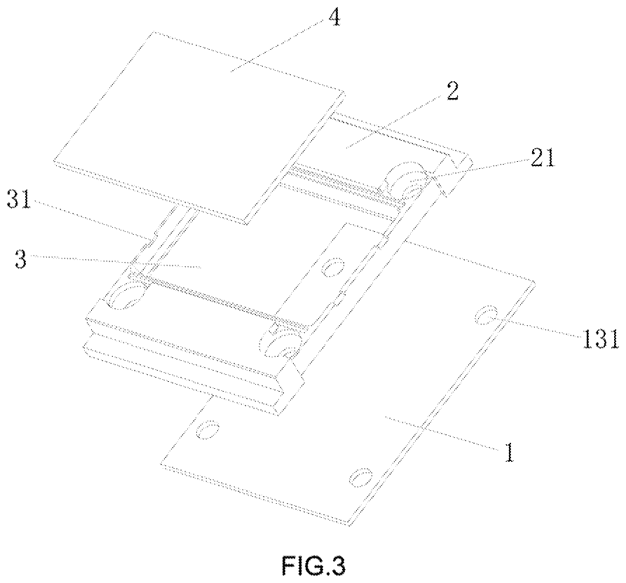

Referring to FIG. 3 to FIG. 6, the lens is preferably a one-stage lens, which is a planar lens 4, a cylindrical lens 5, an integral array lens 6, or a lens group 7.

Referring to FIG. 7, the lens is preferably a two-stage lens, which comprises a primary lens and a secondary lens, wherein the secondary lens is disposed over the primary lens and corresponds to the primary lens in position, the primary lens is a lens group 7, an integral array lens 6 or a cylindrical lens 5, and the secondary lens is a planar lens 4. The primary lens which is the lens group 7, the integral array lens 6 or the cylindrical lens 5 fulfills a condensation effect, and the secondary lens which is the planar lens 4 fulfills a protection effect and can adjust the uniformity of light spots.

Preferably, the substrate 1 is connected to the lens holder 2 by bonding or welding, or with screws.

Referring to FIG. 3, in, one embodiment, the primary lens is a planar lens 4, which is applied within a close range and is low in prices and convenient to clean.

Preferably, notches 31 are formed in the side wall of the fixing cavity 3. Internal and external pressures of the module can be balanced by means of the notches 31, so that the internal pressure of the module will not become excessively high if LEDs generate heat in the operating process.

Preferably, the number of the notches 31 is four, and each of the two sides of the side wall of the fixing cavity 3 is formed with two notches 31.

Preferably, the number of the LED chip units is one or more.

Preferably, the number of the LED chip units is forty.

Preferably, first mounting holes 131 are formed in the substrate 1, second mounting holes 21 are formed in the lens holder 2, the first mounting holes 131 correspond to the second mounting holes 21 in position, and first screws (not shown, the same below) sequentially penetrate through the second mounting holes 21 and the first mounting holes 131 to fix the substrate 1 with the planar lens 4 on a cooling fin. In this way, the substrate of the module can be connected to the cooling fin more stably and can be assembled and disassembled conveniently, so that the substrate of the module can be installed or changed very easily, and time is saved.

Preferably, the number of the second mounting holes 21 and the number of the first mounting holes 131 are two or more.

Preferably, the number of the second mounting holes 21 and the number of the first mounting holes 131 are four, wherein the four first mounting holes 131 formed in corners of the substrate 1, and the four second mounting holes 21 are formed in corners of the lens holder 2. In this way, the module can be fixed more firmly, and heat dissipation of the module is facilitated.

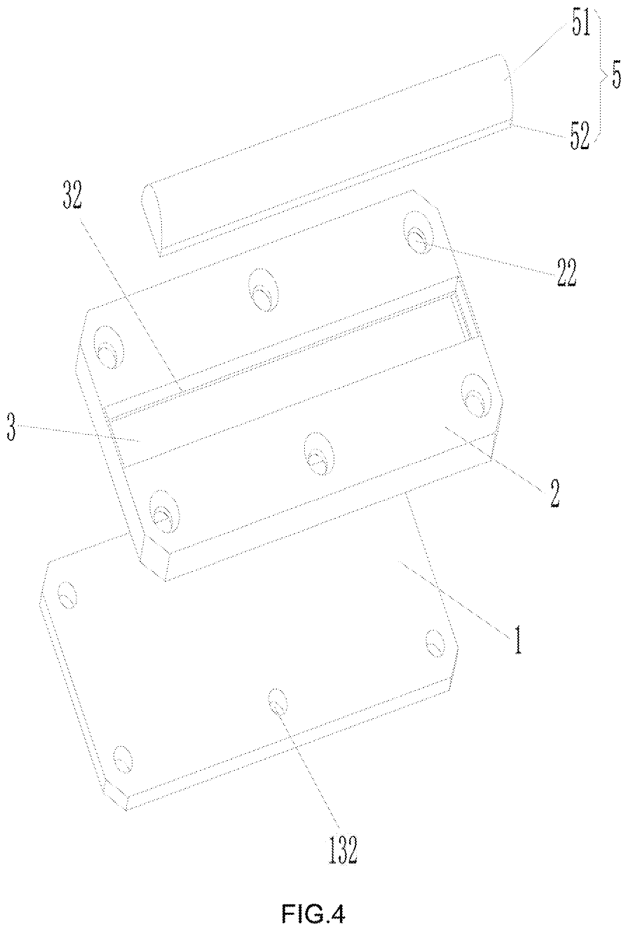

Referring to FIG. 4, in one embodiment, the primary lens or the one-stage lens is a cylindrical lens 5, which has a semicircular section and comprises a middle arc part 51 and flat parts 52 disposed on two sides of the arc part, the arc part 51 is integrated with the flat parts 52, inclined parts 32 are disposed on the side wall of the fixing cavity 3, the cylindrical lens 5 is disposed in the fixing cavity 3, and the flat parts 52 are connected to the inclined parts 32.

Preferably, the section of the cylindrical lens is circular, elliptic or parabolic.

Preferably, third mounting holes 132 are formed in the substrate 1, fourth mounting holes 22 are formed in the lens holder 2, and second screws (not shown, the same below) sequentially penetrate through the fourth mounting holes 22 and the third mounting holes 132 to fix the substrate 1 with the cylindrical lens 5 on a cooling fin.

Preferably, the number of the fourth mounting hole 22 and the number of the third mounting holes are two or more.

Preferably, the number of the fourth mounting holes 22 and the number of the third mounting holes 132 are six, wherein the third mounting holes 132 include four third mounting holes 132 formed in corners of the substrate 1 and two third mounting holes 132 formed in the middle of the substrate 1, and the fourth mounting holes 22 include four fourth mounting holes 22 formed in corners of the lens holder 2 and two fourth mounting holes 22 formed in the middle of the lens holder 2.

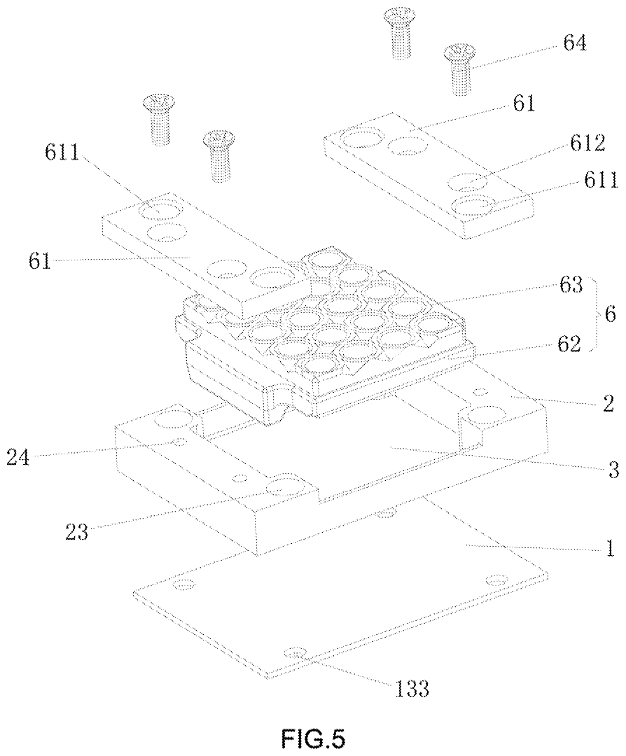

Referring to FIG. 5, in one embodiment, the primary lens or the one-stage lens is an integral array lens 6, that is, adjacent lens units are integrally connected; the integral array lens 6 is processed from the same piece of glass and no gap is formed between the lens nuts of the integral array lens 6, so that dust and other pollutants can be prevented from entering the lens units, which may otherwise contaminate LED chips, and thus, the LED chips are better protected. The design of the integral array lens 6 may vary according to the application range and the light uniformity requirement; and by adoption of the integral array lens, the module can be applied more widely and can adapt to different application ranges and meet different light uniformity requirements by changing the integral array lens.

Preferably, lens pressing pieces 61 are disposed over the integral array lens 6, press against the integral array lens 6, and are connected to the lens holder 2.

Preferably, the integral array lens 6 comprises a lens connecting base 62 and a plurality of array lens units 63, wherein the array lens units 63 are disposed on the lens connecting base 62 and are connected to the lens connecting base 62 and the lens connecting base 62 is disposed in the fixing cavity and is connected to the lens holder 2. In this way, the lens holder 2 and the integral array lens 6 are connected more firmly and can be assembled and disassembled easily.

Preferably, the number of the lens pressing pieces 61 is two, and the two lens pressing pieces 61 are disposed oppositely.

Preferably, each lens unit corresponds to one LED chip unit one set of LED chip units.

Preferably, wavelengths of the LED chip units in each set are completely or partially different. In this way, the LED chips can be used to cure traditional UV glue or ink. Due to the fact that the traditional UV glue or ink contains photoinitiators within multiple wave bands, the LED chips within multiple wave bands can be used to cure the traditional UV glue or ink. Compared with traditional mercury lamps for curing glue or ink, LED lamps are more energy-efficient and higher in efficiency.

Preferably, the distance between the adjacent lens units is greater than or equal to the diameter of the lens units.

Preferably, the distance between the adjacent lens units is smaller than the diameter of the lens units.

Preferably, the plurality of lens units of the integral array lens 6 are all spherical lenses or non-spherical lenses.

Preferably, each set of LED chip units includes four ED chip units with completely different wavelengths.

Preferably, the number of the LED chip units is eighty, and each set includes four LED chip units, that is, there are twenty sets of LED chips which are arranged in a matrix manner.

Preferably, fifth mounting holes 133 are formed in the substrate 1, sixth mounting holes 23 are formed in the lens holder 2, seventh mounting holes 611 are formed in the lens pressing pieces 81, and third screws 64 sequentially penetrate through the seventh mounting holes 611, the sixth mounting holes 23 and the fifth mounting holes 133 to fix substrate 1 with the integral array lens 6 on a cooling fin. In this way, the whole module is connected more firmly and is convenient to assemble and disassemble: and the substrate of the module can be installed or changed easily, and time is saved.

Preferably, the number of the fifth mounting holes 133 the number of the six mounting holes 23 and the number of the seventh mounting holes 611 are four, and the number of the third screws 64 is four.

Preferably, the four fifth mounting holes 133 are formed in corners of the substrate 1, the four sixth mounting holes 23 are formed in corners of the lens holder 2, and the four seventh mounting holes 611 are formed in corners of each lens pressing piece 61. In this way, the module can be fixed more firmly, and heat dissipation of the module is facilitated.

Preferably, eighth mounting holes 612 are formed the lens pressing pieces 61, and ninth mounting holes 24 are formed in the lens holder 2, and fourth screws (not shown, the same below) sequentially penetrate through the eighth mounting holes 612 and the ninth mounting holes 24 to connect the lens pressing pieces 61 to the lens holder 2, so that the integral array lens is fixed. In this way, the whole module can be connected more firmly and can be assembled and disassembled easily, and time is saved.

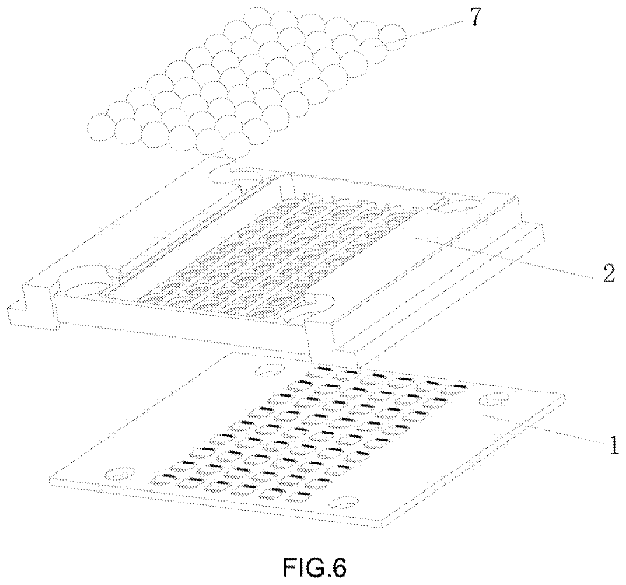

Referring to FIG. 6, in one embodiment the primary lens or the one-stage lens is a lens group 7, that is, adjacent lens units are mutually independent. A plurality of fixing cavities 3 are formed, and the lens units are respectively disposed in the fixing cavities 3.

Preferably the number of the fixing cavities 3 is fifty-four.

Preferably, the LED chip units are connected in series, or in parallel, or both in series and in parallel.

Preferably the lens is made of quartz glass which has good ultraviolet penetrability, so that the light output efficiency is guaranteed.

Preferably, the lens is made of ultraviolet-permeable glass, so that the light output efficiency is guaranteed.

Preferably, the lens is connected to the fixing cavity 3 by bonding. A light and static lens can be connected to the fixing cavity by bonding.

Preferably, the lens is connected to the fixing cavity 3 by means of a fixing structure and bonding. A heavy or movable lens can be connected the fixing cavity in this way.

Preferably, the lens holder 2 is made of metal. The metal lens holder 2 is easy to machine and conducive to heat dissipation.

Preferably, the lens holder 2 is made of ceramic. The ceramic lens holder has the advantage of good insulation performance.

The high-power LED chip back electrode integrating and packaging module provided with a holder in this embodiment has the following beneficial effects:

(1) The module of the invention is simple and firm in structure, easy to assemble and convenient to replace, thus saving time;

(2) The ceramic layer improves the heat dissipation effect and the operating stability and is resistant to high temperature and aging, thus having a longer service life;

(3) The electrode terminal blocks are isolated from the outside and are prevented from being contaminated by external impurities, so that the electrode terminal blocks are better protected, the service life of products is prolonged, the products can be used more safely, the stability of the products is improved, and the high voltage isolation requirements of electronic products are satisfied;

(4) The electrode terminal blocks are connected to external components by crimping, so that the process is made simpler and faster; and

(5) The lens made of glass guarantee the light output efficiency, better protects the LED chips, not prone to aging, simplifies the structure of products, is convenient to clean, and saves costs.

The above embodiments are only preferred ones of the invention, and are not intended to limit the invention. Any modification equivalent substitutions and improvements made on the basis of the spirit and principle of, the invention should also fall within the protection scope of the invention.

What is claimed is:

1. A high-power LED chip back electrode integrating and packaging module provided with a holder, comprising a substrate, a lens holder, and a lens made of glass, wherein the lens holder is disposed over the substrate, wraps the substrate, and has a fixing cavity for accommodating the lens, and the lens is disposed in the fixing cavity and is connected to the lens holder;
the substrate comprises a first circuit layer, a first ceramic layer and a first metal layer, wherein the first circuit layer is disposed over the first ceramic layer and is connected to the first ceramic layer, the first metal layer is disposed under the first ceramic layer and is connected to the first ceramic layer, and first electrode terminal blocks are disposed at two ends of the first metal layer, are connected to the first circuit layer, and are connected to external components by crimping;
and a plurality of first LED chip units are disposed on the first circuit layer, and the lens is disposed over the first LED chip units and corresponds to the first LED chip units in position.

2. The high-power LED chip back electrode integrating and packaging module provided with a holder according to claim 1, wherein the substrate is a DPC substrate or a DBC substrate.

3. The high-power LED chip back electrode integrating and packaging module provided with a holder according to claim 1, wherein the lens is a one-stage lens, which is a planar lens, a cylindrical lens, a lens group, or an integral array lens.

4. The high-power LED chip back electrode integrating and packaging module provided with a holder according to claim 1, wherein the lens is a two-stage lens which comprises a primary lens and a secondary lens, the secondary lens is disposed over the primary lens and corresponds to the primary lens in position, the primary lens is a lens group, an integral array lens or a cylindrical lens, and the secondary lens is a planar lens.

5. The high-power LED chip back electrode integrating and packaging module provided with a holder according to claim 1, wherein the first ceramic layer is made of aluminum nitride or aluminum oxide.

6. The high-power LED chip back electrode integrating and packaging module, provided with a holder according to claim 1, wherein the lens holder is made of metal or ceramic.

7. A high-power LED chip back electrode integrating and packaging module provided with a holder, comprising a substrate, a lens holder, and a lens made of glass, wherein the lens holder is disposed over the substrate, is connected to the substrate by sintering, and has a fixing cavity for accommodating the lens, and the lens is disposed in the fixing cavity and is connected to the lens holder;
the substrate comprises a die bonding layer, a second ceramic layer and a second metal layer, wherein the die bonding layer is disposed over the second ceramic layer and is connected to the second ceramic layer, the second metal layer is disposed under the second ceramic layer and is connected to the second ceramic layer, a second circuit layer disposed on the die bonding layer or the second ceramic layer, and second electrode terminal blocks are disposed at two ends of the second metal layer, are connected to the die bonding layer, and are connected to external components by crimping;
and a plurality of second LED chip units are disposed on the die bonding layer, and the lens is disposed over the second LED chip units and corresponds to the second LED chip units in position.

8. The high-power LED chip back electrode integrating and packaging module provided with a holder according to claim 7, wherein the substrate is a multi-layer sintered ceramic substrate.

9. The high-power LED chip back electrode integrating and packaging module provided with a holder according to claim 7, wherein the lens is a one-stage lens, which is a planar lens, a cylindrical lens, a lens group, or an integral array lens.

10. The high-power LED chip back electrode integrating and packaging module provided with a holder according to claim 7, wherein the lens is a two-stage lens which comprises a primary lens and a secondary lens, the secondary lens is disposed over the primary lens and corresponds to the primary lens in position, the primary lens is a lens group, an integral array lens or a cylindrical lens, and the secondary lens is a planar lens.
